(19) United States
(12) Patent Application Publication
(10) Pub. No.: US 2013/0200402 A1
(43) Pub. Date: Aug. 8, 2013

(54) LIGHT-EMITTING MODULE

(71) Applicant: Shu-Mei Ku, Zhongli City (TW)

(72) Inventor: Cheng-Tao YANG, Zhongli City (TW)

(73) Assignee: Shu-Mei KU, Zhongli City (TW)

(21) Appl. No.: 13/752,937

(22) Filed: Jan. 29, 2013

(30) Foreign Application Priority Data
Feb. 3, 2012 (TW) 101103507

(51) Int. Cl. H01L 33/64

(52) U.S. Cl. CPC H01L 33/64
USPC 257/88

(57) ABSTRACT

A light-emitting module includes a plate substrate, two circuit substrates, at least one LED chip, a plurality of wires and a molding component. The plate substrate includes a plurality of chip carriers protrudingly arranged from an upper surface and a lower surface of the plate substrate. The two circuit substrates directly stack on the upper and lower surface of the plate substrate, respectively, wherein a plurality of openings are arranged corresponding to the chip carriers penetrating therethrough and the upper surface of each chip carrier is at a higher or the same horizontal of the surface of the corresponding circuit substrate. The LED chip is arranged on each chip carrier. Each LED chip and the corresponding circuit substrates are electrically connected with a plurality of wires. Each of LED chips, each of chip carriers, wires and a portion of the circuit substrates are covered with the molding component.

### BACKGROUND OF THE INVENTION

1. Field of the Invention

The present invention is directed to an LED package module, particularly directed to an LED package module using a COB (chip on board) process.

2. Description of the Prior Art

LED (light-emitting diode) is provided with advantages such as being long-lasting, power-saving and highly durable; therefore, lighting apparatuses thereof have become a trend for saving energy and environmental protection and will be widely applied in the future. In general cases for high-luminescence LED lighting devices, lighting modules, usually including a plurality of LED lamps, are directly soldered on ordinary circuit substrates or aluminum substrates. Additional heating dissipating elements, such as heat sink fins installed under the substrate, may be configured for improving effects in heat dissipation. However, in addition to issues of heat dissipation, common LED lighting devices provided with lighting collimation properties fail to achieve wide lighting angles in comparison to 270 degrees for ordinary bulbs available at present. Hence, it is now an important goal to solve issues regarding heat dissipation and lighting collimation of LED lighting devices.

### SUMMARY OF THE INVENTION

To solve the above-mentioned problems, one objective of the present invention is directed to providing a light-emitting module having a plate substrate configured with a plurality of LED chips at both sides, particularly at the peripheral region of the plate substrate. The light-emitting module of the present invention may provide a 270-degree lighting path whether lighting vertically or horizontally

To achieve above objectives, a light-emitting module according to one embodiment of the present invention includes a plate substrate including a plurality of chip carriers protrudingly arranged from an upper surface and a lower surface of the plate substrate, wherein the plate substrate is made of a high thermal conductive material and the plurality of chip carriers are arranged at a peripheral region of the plate substrate; two circuit substrates directly stacking on the upper and lower surface of the plate substrate, respectively, wherein a plurality of openings are arranged corresponding to each of the chip carriers penetrating therethrough and the upper surface of each of the chip carriers are at a higher or the same horizontal in comparison to the surface of the corresponding circuit substrate; at least one LED chip arranged on each of the chip carriers; a plurality of wires electrically connecting each of the LED chips and the corresponding circuit substrates; and a molding component covering each of the LED chips, each of the chip carriers, wires and a portion of the circuit substrate.

A light-emitting module according to another embodiment of the present invention includes a plate substrate, wherein the plate substrate is made of a high thermal conductive material; a plurality of chip carriers are arranged at a peripheral region of the plate substrate; and a heat dissipation joint part is arranged at one side or one surface of the plate substrate; two circuit substrates directly stacking on the upper and lower surface of the plate substrate, respectively, wherein a plurality of openings are arranged corresponding to each of the chip carriers penetrating therethrough; at least one LED chip arranged on each of the chip carriers; a plurality of wires electrically connecting each of the LED chips and the corresponding circuit substrates; a molding component covering each of the LED chips, chip carriers, wires and a portion of the circuit substrate; and a heat sink, wherein the plate substrate are vertically or horizontally joined to the heat sink through the heat dissipation joint part.

Other advantages of the present invention will become apparent from the following descriptions taken in conjunction with the accompanying drawings wherein certain embodiments of the present invention are set forth by way of illustration and examples.

### BRIEF DESCRIPTION OF THE DRAWINGS

The foregoing aspects and many of the accompanying advantages of this invention will become more readily appreciated as the same becomes better understood by reference to the following detailed descriptions, when taken in conjunction with the accompanying drawings, wherein:

FIGS. 1A and 1B are schematic diagrams illustrating an embodiment of the present invention;

FIG. 2 is a schematic diagram illustrating an embodiment of the present invention;

FIG. 3 is a partially enlarged view of one embodiment of the present invention;

FIGS. 4A and 4B are schematic diagrams illustrating an embodiment of the present invention;

FIG. 5 is a schematic diagram illustrating an embodiment of the present invention;

FIG. 6 is a schematic diagram illustrating an embodiment of the present invention;

FIG. 7 is a schematic diagram illustrating an embodiment of the present invention; and

FIG. 8 is a schematic diagram illustrating an embodiment of the present invention.

### DESCRIPTION OF THE PREFERRED EMBODIMENT

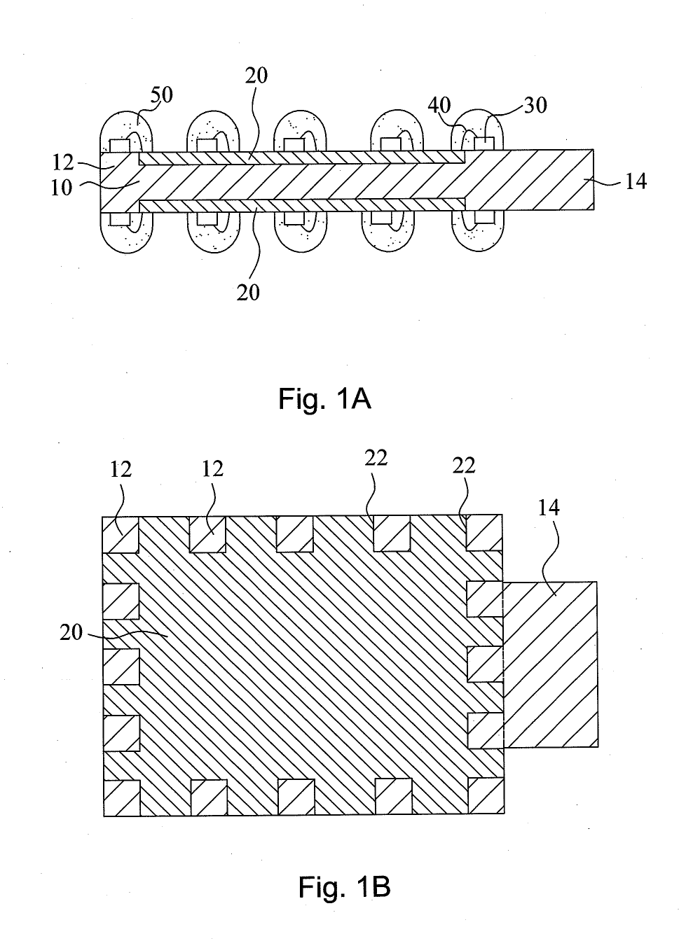

The detailed description is now illustrated as following. It is noted that the described preferred embodiments are merely illustrative instead of being used for limiting the scope of the present invention. FIGS. 1A and 1B are schematic diagrams illustrating an LED package module according to one embodiment of the present invention. FIG. 1B is a top view illustrating a plate substrate and a circuit substrate illustrated in FIG. 1A.

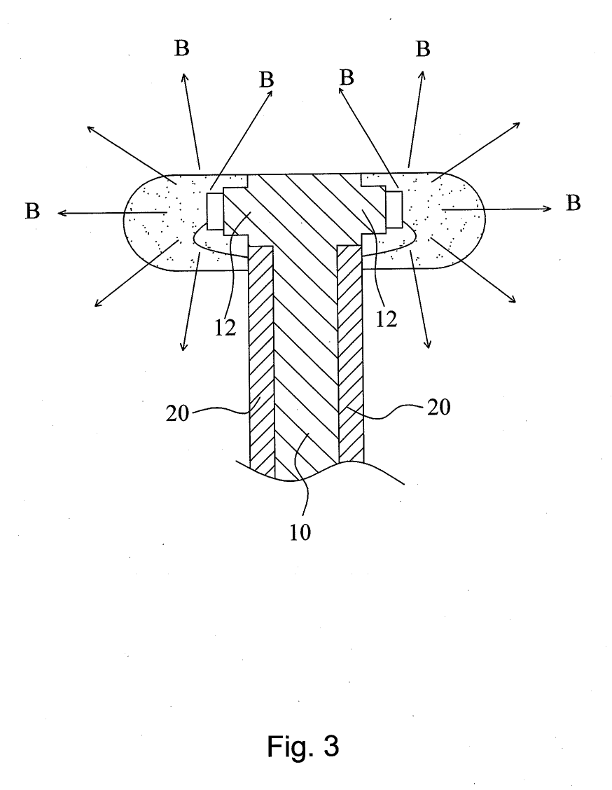

In the present embodiment, referring to FIGS. 1A and 1B, a light-emitting module includes a plate substrate 10. A plurality of chip carriers 12 are arranged on the upper and lower surface of the plate substrate 10 and protrude from the upper and lower surface of the plate substrate 10. In addition, a plurality of chip carriers 12 are also arranged at a peripheral region of the plate substrate 10. Two circuit substrates 20 directly stack on the upper and lower surface of the plate substrate 10, respectively. A plurality of openings 22 are arranged on the circuit substrates 20 corresponding to each of the chip carriers 12 penetrating therethrough. In the present embodiment, a top surface of the chip carrier 12 is at the same horizontal as that of the circuit substrates 20, as illustrated in FIG. 1A. It is understood that the upper surface of the chip carrier 12 may protrude from or be higher than the upper surface of the circuit substrates 20, as illustrated in FIG. 3.

To continue from the above description, at least one LED chip 30 is arranged on each of the chip carriers 12. The LED chips 30 and the circuit substrates 20 are electrically connected with a plurality of wires 40. Each of the LED chips 30, chip carriers 12, wires 40 and a portion of the circuit substrates 20 are covered with a molding component 50.

It is understood for those skilled in the art that the upper surface of the chip carriers 12 is at the same horizontal as that of the circuit substrate 20 in the above embodiment but the upper surface of the chip carriers 12 may be a little concave in an actual manner due to the stacking process of the plate substrate 10 and the circuit substrates 20. The plate substrate of the present invention may be made of high thermal conductive materials such as metal. In one embodiment, the circuit substrates 20 may be a printed circuit board. In one embodiment, the circuit substrate 20 may include an insulating layer, a wire layer and a solder resist layer.

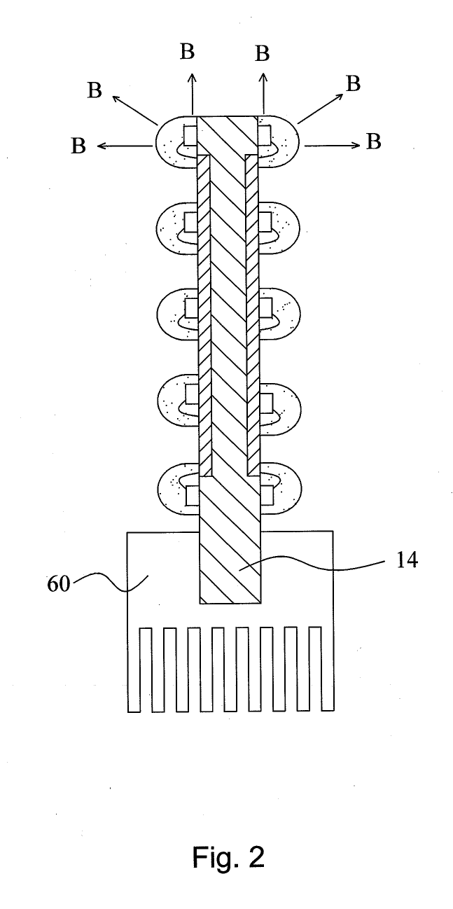

Referring to FIGS. 1A, 1B and 2 simultaneously, a heat dissipation joint part 14 is arranged at one side of the plate substrate 10. The plate substrate 10 may be vertically joined to the heat sink 60 through the heat dissipation joint part 14.

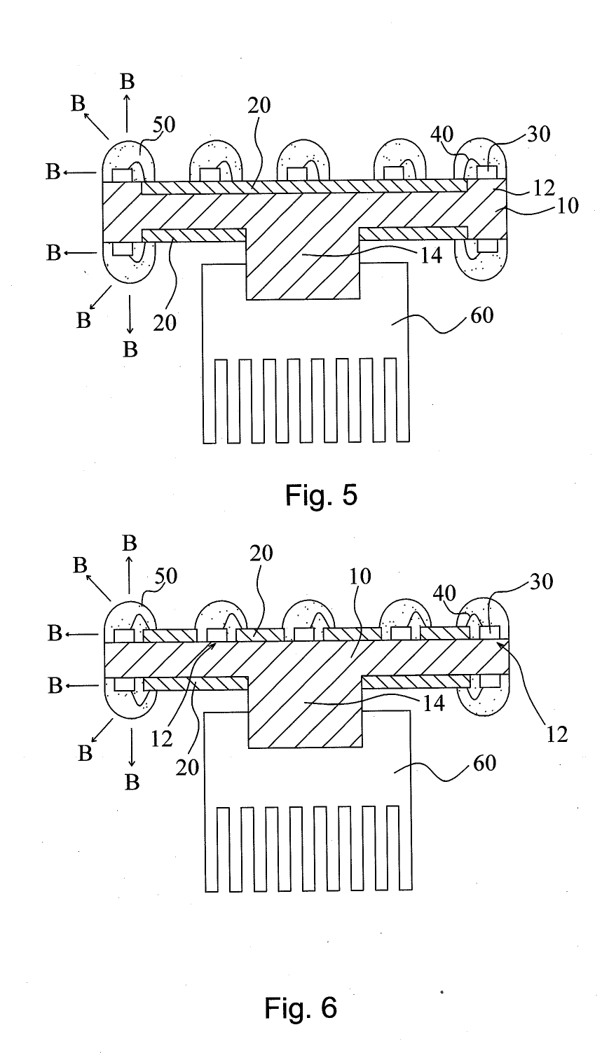

In one embodiment, referring to FIG. 5, a heat dissipation joint part 14 may be arranged at a surface of the plate substrate 10 so that the plate substrate 10 are horizontally joined to the heat sink 60 through the heat dissipation joint part 14. It is understood that the joint part connected to the heat sink is not limited to the protruding joint part of the heat dissipation joint part and may be a surface region of the plate substrate by using a fastening element.

As illustrated in FIGS. 3 and 5, the LED chips 30 may be arranged at the edges of both sides of the plate substrate 10 in the present invention as so to provide a lighting path such as an optical path B. Therefore, the light-emitting module of the present invention may provide a 270-degree lighting path equivalent to conventional bulb whether lighting vertically or horizontally so as to solve the problem of limited lighting angles of conventional LED light fixtures. In one embodiment, it goes without any doubt that the chip carriers 12 may be configured at a center region or other non-peripheral regions of the plate substrate 10.

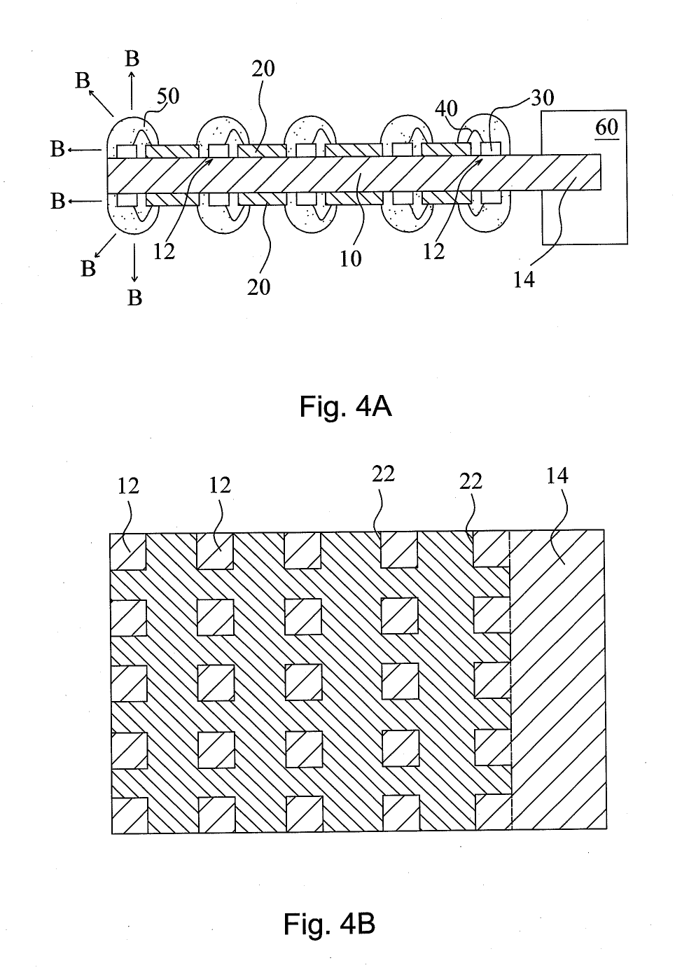

Continuing from the above, referring to FIGS. 4A and 4B, wherein FIG. 4A is a top view of the plate substrate and circuit substrate illustrated in FIG. 4A. In one embodiment, the light-emitting module includes a plate substrate 10. In the present embodiment, a plurality of chip carriers 12 are arranged on a peripheral region of the plate substrate 10 and a heat dissipation joint part 14 is arranged at one side of the plate substrate 10. Two circuit substrates 20 directly stack on the upper and lower surface of the plate substrate 10, respectively. A plurality of openings 22 are arranged on the circuit substrates 20 and configured for exposing each of the chip carriers 12.

Continuing from the above description, at least one LED chip 30 is arranged on each of the chip carriers 12. The LED chips 30 and the circuit substrates 20 are electrically connected with a plurality of wires 40. Each of the LED chips 30, each of the chip carriers 12, wires 40 and a portion of the circuit substrates 20 are covered with a molding component 50. In addition, the plate substrate 10 may be vertically joined to the heat sink 60 through the heat dissipation joint part 14. In one further embodiment, referring to FIG. 6, a heat dissipation joint part 14 may protrude from a surface of the plate substrate 10 so that the plate substrate 10 are horizontally joined to the heat sink 60 through the heat dissipation joint part 14.

In one embodiment, the chip carriers 12 may be configured at a center region or other non-peripheral regions of the plate substrate 10.

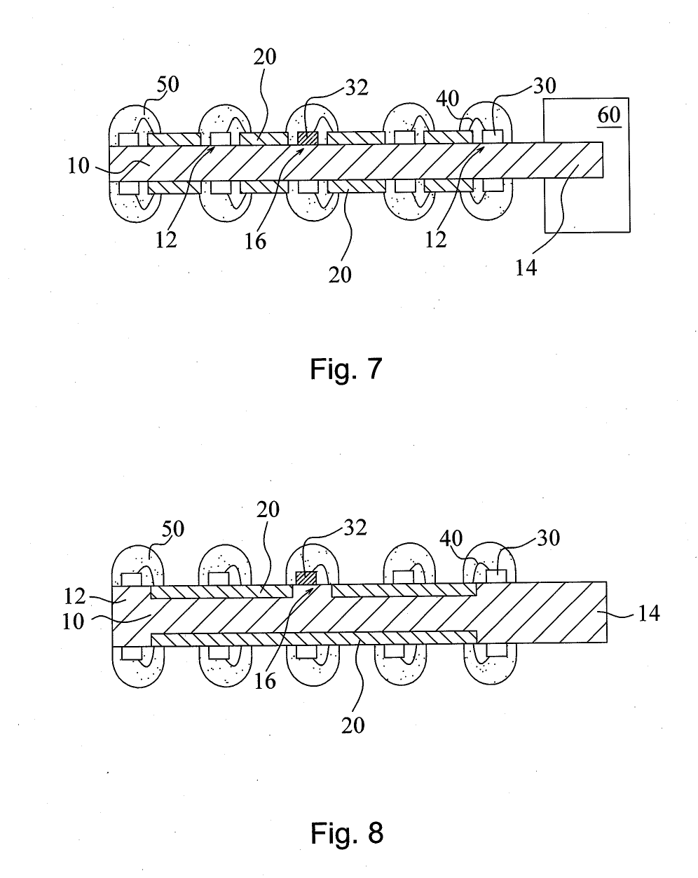

It is understood for those skilled in the art from the above embodiments that the setting density for chip carriers 12 or the LED chips 30 may be designed based on various lighting demands. In the present invention, a controller chip may be integrated with the light-emitting module. The light-emitting module may include both lighting units and controller units in this way so as to lower the assembly configuration and process as well cost of lamp products. Furthermore, heat is generated during the operation of the controller chip and heat accumulation may cause lower product life. The light-emitting module of the present invention may provide excellent heat dissipation and solve the heat dissipation problem of controller chips at the same time. Referring to FIGS. 7 and 8, in another embodiment, a controller chip 32 may be configured on a controller chip carrier 16 and electrically connected to the circuit substrates 20 via the wires 40. Here, the controller chip carrier 16 may be at the same (FIG. 7) or a higher horizontal (FIG. 10) in comparison to the surface of the plate substrate 10. It is certain that the upper surface of controller chip carriers 16, the same as the chip carrier 12 may be at the same or a higher horizontal in comparison to the surface of the circuit substrate 20.

In the present invention, the heat no matter generated by the chip or the internal circuit of the circuit substrates may be directly dissipated by the plate substrate. Additionally configured heat sinks, if needed, may also strengthen the efficiency for heat dissipation. The chip carriers of the present invention may be configured at the peripheral region of the plate substrate. In another embodiment, the openings of circuit substrates may be located at the peripheral region of the plate substrate and may be open or sealed. In the case of open openings (as illustrated in the figure), some chip carriers would be exposed from the peripheral region of the circuit substrates, the lighting angles of the LED chips at the peripheral region of the plate substrate would not be affected whether the chip carriers protrude from the surface of the plate substrate or not. In the case of sealed openings (not illustrated), it is preferred that the upper surface of the chip carriers is at the same or a higher horizontal in comparison to the surface of the corresponding circuit substrates.

It is understood that an adhesive reagent for mounting chips to the chip carriers are required and it is kept electrically insulated between the plate substrate and the circuit substrate. The materials and techniques used therein are hence abbreviated since it is commonly known for those skilled in the art. The heat sink used in the present invention is not limited to heat sink fins but refers to those capable of joining to the heat sink through the heat dissipation joint part so as to assist in heat dissipation.

In addition, the upper surface of the plate substrate may be configured with a highly reflective layer made of metallic silver or other highly reflective materials. Metallic silver is capable of providing excellent reflective effect and may be provided onto the plate substrate by electroplating.

To sum up, the present invention adopts two circuit substrates directly stacking on the upper and lower surface of the plate substrate so as to achieve direct heat dissipation of the circuit substrate and LED chips toward the plate substrate. Processes and materials used in the present invention may be simplified and cost for processes and materials may be lowered since components used in the structures of the present invention are simple. Furthermore, the peripheral region of the both side of the plate substrate of the present invention is configured with a plurality of LED chips. Therefore, the present invention, no matter lighting in a vertical or horizontal manner, may effectively improve the conventional drawbacks of lighting collimation for LED in comparison to 270 degrees wide lighting angles for ordinary bulbs.

While the invention can be subject to various modifications and alternative forms, a specific example thereof has been shown in the drawings and is herein described in detail. It should be understood, however, that the invention is not to be limited to the particular form disclosed, but on the contrary, the invention is to cover all modifications, equivalents, and alternatives falling within the spirit and scope of the appended claims.

What is claimed is:

1. A light-emitting module, including
a plate substrate including a plurality of chip carriers protrudingly arranged from an upper surface and a lower surface of the plate substrate, wherein the plate substrate is made of a high thermal conductive material and the plurality of chip carriers are arranged at a peripheral region of the plate substrate;
two circuit substrates directly stacking on the upper and lower surface of the plate substrate, respectively, wherein a plurality of openings are arranged corresponding to each of the chip carriers penetrating therethrough and the upper surface of each of the chip carriers are at a higher or the same horizontal in comparison to the surface of the corresponding circuit substrate;
at least one LED chip arranged on each of the chip carriers;
a plurality of wires electrically connecting each of the LED chips and the corresponding circuit substrates; and
a molding component covering each of the LED chips, each of the chip carriers, wires and a portion of the circuit substrates.

2. The light-emitting module as claimed in claim 1, wherein a heat dissipation joint part is arranged at one side of the plate substrate.

3. The light-emitting module as claimed in claim 2, further including:
a heat sink, wherein the plate substrate is vertically joined to the heat sink through the heat dissipation joint part.

4. The light-emitting module as claimed in claim 1, wherein a heat dissipation joint part is arranged at a surface of the plate substrate.

5. The light-emitting module as claimed in claim 4, further including:
a heat sink, wherein the plate substrate is horizontally joined to the heat sink through the heat dissipation joint part.

6. The light-emitting module as claimed in claim 1, wherein the plurality of the chip carriers are arranged in a center region of the plate substrate.

7. The light-emitting module as claimed in claim 1, further including:
a controller chip configured on a controller chip carrier and electrically connected to the circuit substrate, wherein the controller chip carrier is at a higher or the same horizontal in comparison to the upper surface of the plate substrate.

8. A light-emitting module, including
a plate substrate, wherein the plate substrate is made of a high thermal conductive material;
a plurality of chip carriers are arranged at a peripheral region of the plate substrate; and
a heat dissipation joint part is arranged at one side or one surface of the plate substrate;
two circuit substrates directly stacking on the upper and lower surface of the plate substrate, respectively, wherein a plurality of openings are arranged corresponding to each of the chip carriers penetrating therethrough;
at least one LED chip arranged on each of the chip carriers;
a plurality of wires electrically connecting each of the LED chips and the corresponding circuit substrates;
a molding component covering each of the LED chips, chip carriers, wires and a portion of the circuit substrates; and
a heat sink, wherein the plate substrate is vertically or horizontally joined to the heat sink through the heat dissipation joint part.

9. The light-emitting module as claimed in claim 8, wherein some of the plurality of the chip carriers are arranged in a center region of the plate substrate.

10. The light-emitting module as claimed in claim 8, further including:
a controller chip configured on a controller chip carrier and electrically connected to the circuit substrates, wherein the controller chip carrier is at the same or a higher horizontal in comparison to the upper surface of the plate substrate.
